(19) United States
(12) Patent Application Publication
(10) Pub. No.: US 2025/0274125 A1
(43) Pub. Date: Aug. 28, 2025

(54) APPARATUS INCLUDING SLEW RATE CONTROL CIRCUIT

(71) Applicant: MICRON TECHNOLOGY, INC., Boise, ID (US)

(72) Inventors: Hyunui Lee, Pyeongtaek (KR); Yasuo Satoh, Ibraski (JP)

(73) Assignee: MICRON TECHNOLOGY, INC., Boise, ID (US)

(21) Appl. No.: 19/035,535

(22) Filed: Jan. 23, 2025

Related U.S. Application Data
(60) Provisional application No. 63/557,013, filed on Feb. 23, 2024.

(51) Int. Cl. H03K 19/0944; H10B 12/00

(52) U.S. Cl. CPC H03K 19/0944; H10B 12/50

(57) ABSTRACT

Some embodiments of the disclosure provide an apparatus including a logic circuit and a capacitive device. The logic circuit receives a target signal. The capacitive device includes one terminal coupled to a first node on an output side of the logic circuit and another terminal coupled to a second node on an input side of the logic circuit.

### CROSS REFERENCE TO RELATED APPLICATION(S)

This application claims priority to U.S. Provisional Application No. 63/557,013, filed Feb. 23, 2024. The aforementioned application is incorporated herein by reference, in its entirety, for any purpose.

### BACKGROUND

High data reliability, high speed of memory access, low power consumption, and reduced chip size are some features that are demanded from a semiconductor memory device, such as a dynamic random-access memory (DRAM). A memory device may use a slew rate control circuit for slew rate control of various signals, such as a clock signal, a data signal, and a command and address signal. A slew rate control may regulate a falling edge or a rising edge of a signal to, for example, delay the signal or change a duty cycle.

### BRIEF DESCRIPTION OF THE DRAWINGS

FIG. 1 is a block diagram of an example semiconductor device according to an embodiment of the disclosure.

FIGS. 2A-2D are schematic diagrams of example slew rate control circuits according to an embodiment of the disclosure.

FIG. 2E is a schematic diagram of serially-coupled slew rate control circuits according to an embodiment of the disclosure.

FIGS. 2F and 2G are schematic diagrams of example slew rate control circuits according to an embodiment of the disclosure.

FIG. 2H is a schematic diagram of an example slew rate control circuit including a NAND logic circuit according to an embodiment of the disclosure.

FIG. 3 is a timing diagram of an example slew rate control circuit according to an embodiment of the disclosure.

FIGS. 4A-4D are schematic diagrams of example slew rate control circuits and example switch circuits according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

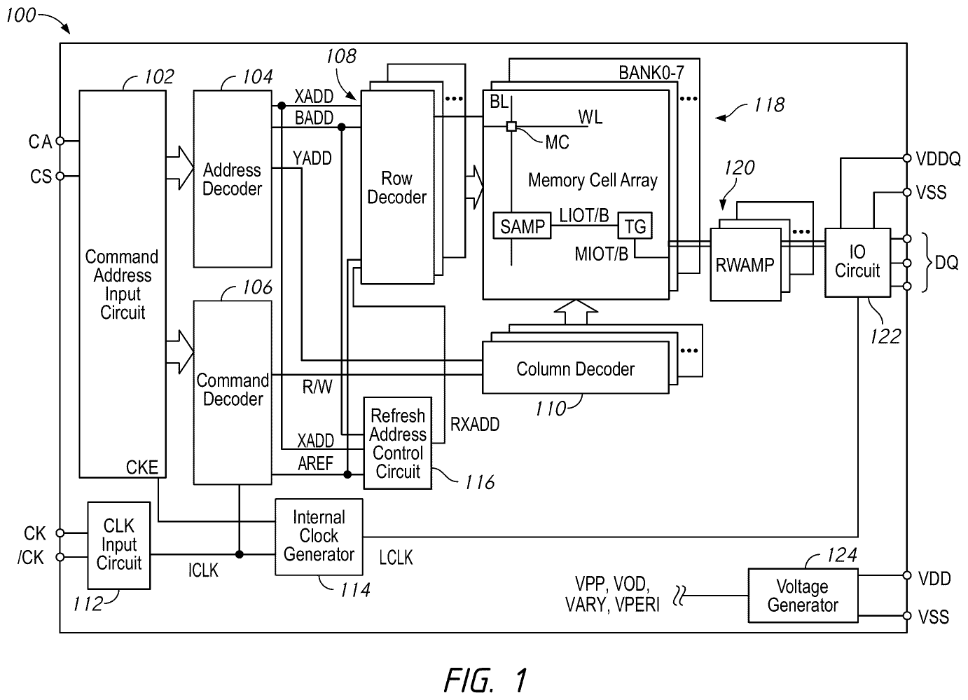

FIG. 1 is a block diagram of an example semiconductor device 100 according to an embodiment of the disclosure. The semiconductor device 100 may be one example of an apparatus. The semiconductor device 100 may be or include a semiconductor memory device, such as a dynamic random access memory (DRAM). The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL, a plurality of bit lines BL, and a plurality of memory cells MC arranged at intersections of the plurality of word lines WL and the plurality of bit line BL. Selection of the word line WL is performed by a row decoder 108 and selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP) of the memory array 118. Read data from the bit line BL is amplified by the sense amplifier SAMP, and transferred to read/write amplifiers (RWAMPs) 120 over complementary local data lines (LIOT/B), transfer gate (TG), and complementary main data lines (MIOT/B) which are coupled to RWAMP 120. Conversely, write data outputted from RWAMP 120 is transferred to the sense amplifier SAMP over the complementary main data lines MIOT/B, the transfer gate TG, and the complementary local data lines LIOT/B, and written in the memory cell MC coupled to the bit line BL.

The semiconductor device 100 may employ a plurality of external terminals that include command and address (CA) terminals coupled to a command and address bus to receive commands and addresses and a chip select (CS) signal, clock terminals to receive clocks CK and/CK, data terminals DQ to provide data, and power supply terminals to receive power supply potentials VDD, VSS, and VDDQ.

The clock terminals are supplied with external clocks CK and/CK that are provided to a clock input circuit 112. The external clocks CK and/CK may be complementary. The clock input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal clocks LCLK are provided to an input and output (IO) circuit 122 to time operation of circuits included in the IO circuit 122, for example, to data receivers to time the receipt of write data. In some instances, the internal clocks may also be passed to other internal components, such as RWAMP 120.

The CA terminals may be supplied with memory addresses. The memory addresses supplied to the CA terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The CA terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to the command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The semiconductor device 100 may receive an access command which is a read command. When a read command is received, and a bank address, a row address and a column address are timely supplied with an activate command and the read command, read data is read from memory cells in the memory array 118 corresponding to the row address and column address. The read command is received by the command decoder 106, which provides internal commands so that the read data from the memory cells in the memory array 118 is provided to RWAMP 120. The read data is output to outside the semiconductor device 100 from the data terminals DQ via the IO circuit 122.

The semiconductor device 100 may receive an access command which is a write command. When the write command is received, and a bank address, a row address and a column address are timely supplied with an activate command and the write command, write data is supplied through the DQ terminals to RWAMP 120. The write data supplied to the data terminals DQ is written to the memory cells in the memory array 118 corresponding to the row address and column address. The write command is received by the command decoder 106, which provides internal commands so that the write data is received by data receivers in the IO circuit 122. Write clocks may also be provided to the external clock terminals for timing the receipt of the write data by the data receivers of the IO circuit 122. The write data is supplied via the IO circuit 122 to RWAMP 120.

The semiconductor device 100 may also receive commands causing it to carry out one or more refresh operations as part of a self-refresh mode. In some embodiments, the self-refresh mode command may be externally issued to the semiconductor device 100. In some embodiments, the self-refresh mode command may be periodically generated by a component of the device. In some embodiments, when an external signal indicates a self-refresh entry command, the refresh signal AREF may also be activated.

The power supply terminals are supplied with power supply potentials VDD and VSS. The power supply potentials VDD and VSS are supplied to an internal voltage generator circuit 124. The internal voltage generator circuit 124 generates various internal potentials such as VPP, VOD, VARY, VPERI, and the like based on the power supply potentials VDD and VSS.

The power supply terminals are also supplied with power supply potential VDDQ. The power supply potential VDDQ is supplied to the IO circuit 122. The power supply potential VDDQ may be the same potentials as the power supply potential VDD in one embodiment of the disclosure. The power supply potential VDDQ may be different potentials from the power supply potential VDD in another embodiment of the disclosure. The power supply potential VDDQ are used for the IO circuit 122 so that power supply noise generated by the IO circuit 122 does not propagate to the other circuit blocks.

In some embodiments of the disclosure, the semiconductor device 100 may further include a slew rate control circuit to control slew rates of various signals, such as a clock signal, a data signal, and a command and address signal. For example, a slew rate control circuit to provide slew rate control of clock signals may be included in the clock input circuit 112. A slew rate control circuit for internal clock signals may be included in the internal clock generator 114 or the IO circuit 122 on the internal clock signal path. A slew rate control circuit for data signals may be included in the IO circuit 122 on the data signal path. A slew rate control circuit for command and address signals may be included in the command/address input circuit 102. Slew rate control circuits may be located outside of these circuits where target signals can be received.

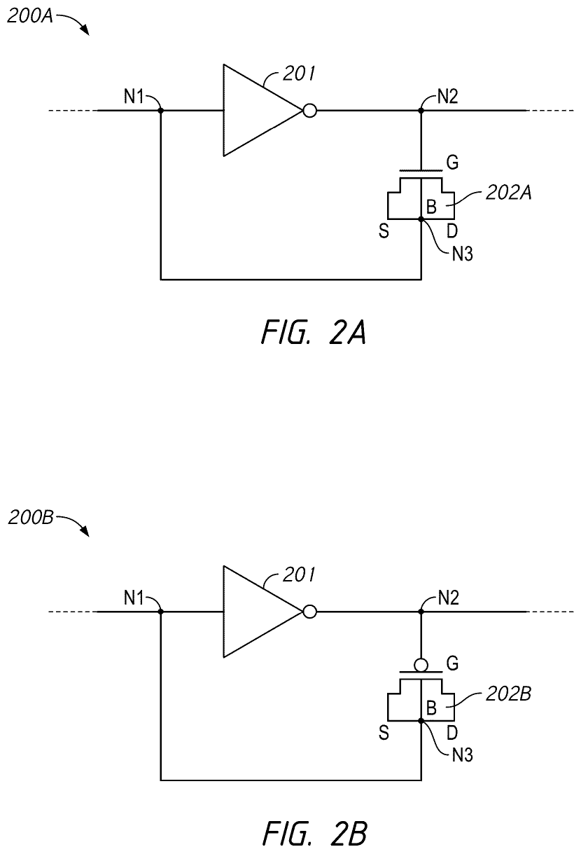

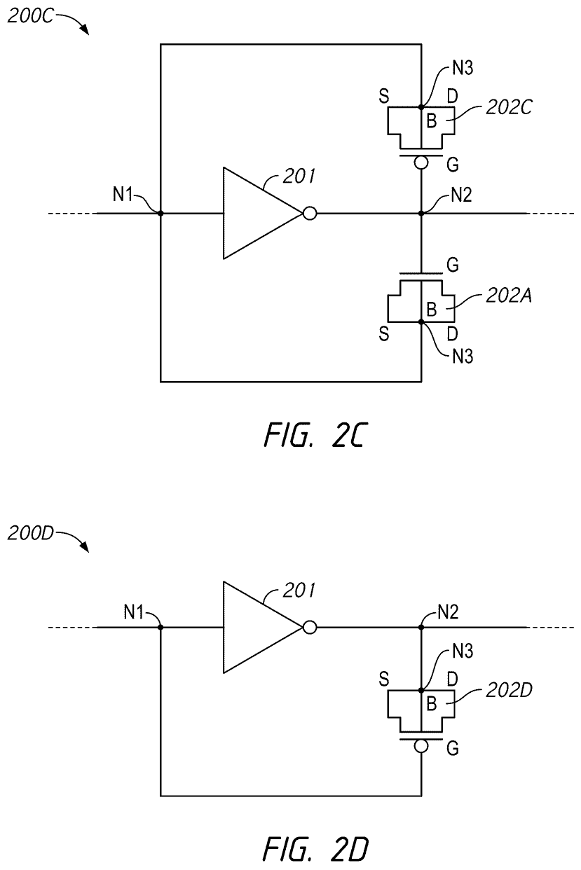

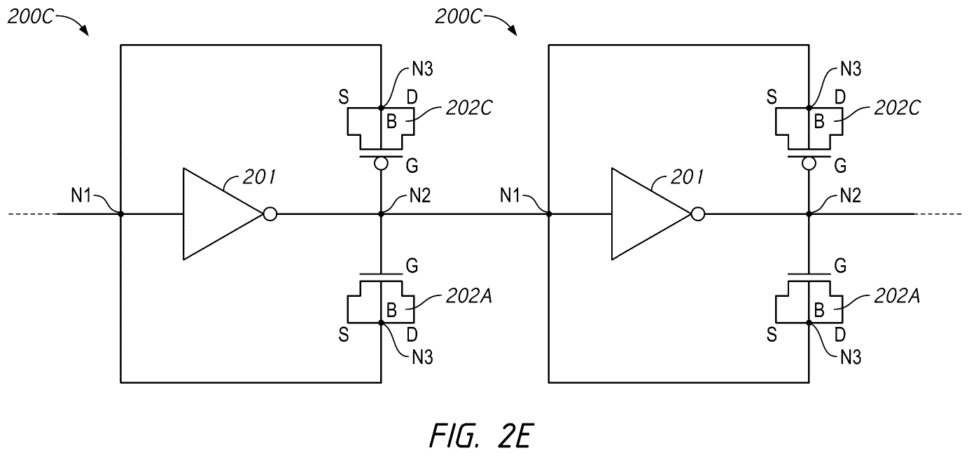

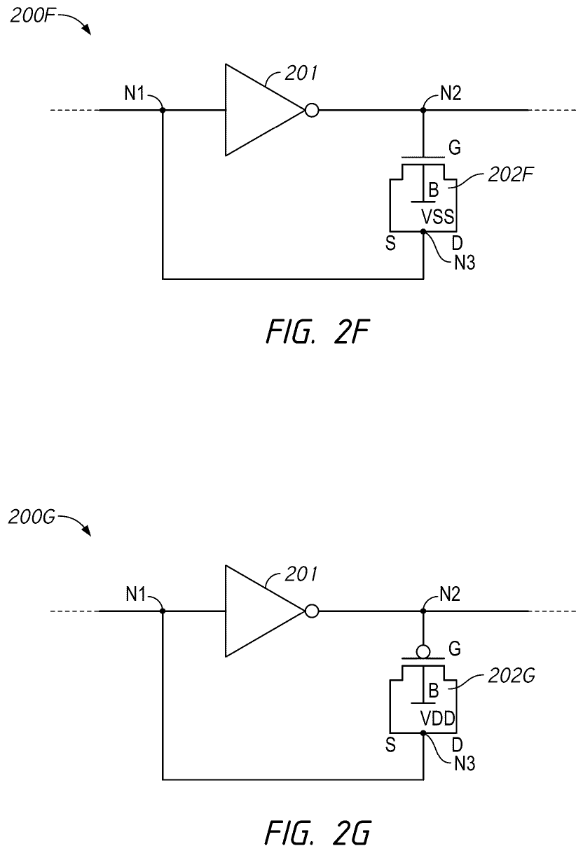

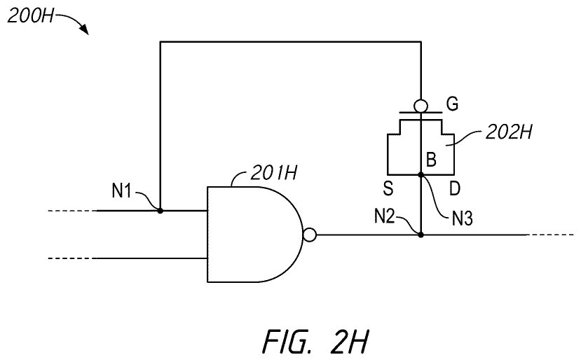

FIGS. 2A-2D are schematic diagrams of example slew rate control circuits according to an embodiment of the disclosure. In FIG. 2A, a slew rate control circuit 200A includes a logic circuit, such as an inverter (or a NOT logic gate) 201, on a circuit input side, and a capacitive device 202A on a circuit output side. On the circuit input side, an input of the inverter 201 may be coupled to a signal line at, for example, a node NI to receive a target signal of slew rate control. The inverter 201 converts a polarity of the target signal. The inverter 201 may include a transistor inverter. The transistor inverter may include a metal-oxide-semiconductor (MOS) transistor inverter, such as an n-channel type MOS (NMOS) transistor and a p-channel type MOS (PMOS) transistor inverter.

On the circuit output side, one terminal of the capacitive device 202A is coupled to an output of the inverter 201 at a node N2. The node N2 may be regarded as a target node of the slew rate control of the signal output from the inverter 201. In the slew rate control circuit 200A, the capacitive device 202A is also coupled to the input of the inverter 201 at the node N1. The node N1 may be regarded as a previous node on the input side of the inverter 201 in comparison with the node (or target node) N2 on the output side of the inverter 201.

The capacitive device 202A may be a transistor that functions as a capacitor. The transistor may be a metal-oxide-semiconductor (MOS) field effect transistor. The MOS transistor may be an n-channel type MOS (NMOS) transistor or a p-channel type MOS (PMOS) transistor. In the slew rate control circuit 200A, the capacitive device 202A is an NMOS transistor. Such capacitive device may also be referred to as an NMOS transistor capacitive device. A gate (G) of the NMOS transistor is coupled to the output of the inverter 201 at the node N2. At least a body (B) of the NMOS transistor is coupled to the input of the inverter 201 at the node N1. In the example, a source(S) and a drain (D) of the NMOS transistor are also coupled to the input of the inverter 201 at the node N1. In one instance, the source(S), the drain (D), and the body (B) of the NMOS transistor are commonly coupled to the input of the inverter 201 at the node N1. In another instance, the source(S), the drain (D), and the body (B) are tied together by being coupled to each other at a node N3, and the node N3 is coupled to the node N1.

Compared with a case where S, D, and B of a MOS transistor conductive device are coupled to ground or a negative power terminal (to, for example, receive a power supply potential such as VSS), the slew rate control circuit 200A of the present embodiment realizes capacitance at the node N1 in addition to capacitance at the node N2. In other words, the slew rate control by the slew rate control circuit 200A uses the capacitance at the nodes N1 and N2. This increases the total effective capacitance of the slew rate control circuit 200A without increasing the size of the capacitive device 202A. Furthermore, because of the tied S-D-B configuration of the MOS transistor, there is no voltage difference among S, D, and B, which improves reliability of the slew rate control. Still furthermore, the slew rate control circuit 200A can greatly increase delay of a falling edge and/or a rising edge of the target signal output from the inverter 201 at the node N2 while not adding delay at the node N1 before entering the inverter 201. For example, the signal delay at the node N2 by the slew rate control circuit 200A may be about two times greater than the case where there is capacitance only at the node N1.

In FIG. 2B, a slew rate control circuit 200B includes a capacitive device 202B which is a PMOS transistor. Such capacitive device may also be referred to as a PMOS transistor capacitive device. A gate (G) is coupled to the node N2, and a source(S), a drain (D), and a body (B) are tied together at the node N3 and coupled to the node N1.

In FIG. 2C, a slew rate control circuit 200C includes the NMOS transistor capacitive device 202A and a PMOS transistor capacitive device 202C which are both coupled between the node N2 and the node N1. Gates (G) of the NMOS and PMOS transistor capacitive devices 202A and 202C are commonly coupled to the node N2, whereas sources(S), drains (D), and bodies (B) of the NMOS and PMOS transistor capacitive devices 202A and 202C are tied together at the respective nodes N3 and commonly coupled to the node N1.

In FIG. 2D, unlike the slew rate control circuits 200A-200C of FIGS. 2A-2C, a slew rate control circuit 200D includes a capacitive device 202D which is a PMOS transistor having a gate (G) coupled to the node N1 and a source(S), a drain (D), and a body (B) coupled to each other at the node N3 and coupled to the node N2. In other words, the G and S-D-B configuration is reversed or flipped from that of the PMOS transistor capacitive device 202B of FIG. 2B. In another example, the PMOS transistor capacitive device 202D may be replaced with an NMOS transistor capacitive device having the reversed G and S-D-B configuration from that of the NMOS transistor capacitive device 202A of FIG. 2A.

In a similar manner to the slew rate control circuit 200A, the slew rate control circuits 200B-D according to the present embodiments realize greater total capacitance without increasing the capacitive device size, improve slew rate control reliability, and achieve greater delay of a target signal.

In some embodiments, a plurality of slew rate control circuits can be arranged in series on a signal path. FIG. 2E is a schematic diagram of serially-coupled slew rate control circuits according to an embodiment of the disclosure. As one example, in FIG. 2E, two of the slew rate control circuit 200C of FIG. 2C are coupled to each other in series. The node N1 of the first slew rate control circuit 200C may be coupled to a signal line to receive a target signal, and the node N2 of the first slew rate control circuit is coupled to the node N1 of the second slew rate control circuit 200C. This configuration provides multiple slew rate control stages on the signal path. The serially-coupled slew rate control circuits may be any combination of the slew rate control circuits 200A-200D of FIGS. 2A-2D.

In some embodiments, the body (B) of the NMOS/PMOS transistor capacitive devices 202A-D may be electrically independent of the body of the transistor of the inverter 201. For example, the body (B) of the NMOS/PMOS transistor capacitive devices 202A-C may be coupled to the node N1 electrically independently from the body of the transistor of the inverter 201. Likewise, the body (B) of the PMOS transistor capacitive device 202D may be coupled to the node N2 electrically independently from the body of the transistor of the inverter 201.

In some embodiments, the MOS transistors as the capacitive devices 202A-202D may be metal-insulator-silicon (MIS) transistors. The insulator may be a non-oxide insulator. The same or substantially the same advantages as those by the MOS transistor capacitive devices can also be achieved by the MIS transistor capacitive devices.

In some embodiments, the body of the transistor capacitive device may be coupled to the power supply terminal or any other terminals or lines as appropriate to be supplied with a fixed voltage, such as power supply potentials VDD and VSS, whereas the source and the drain are coupled to one of the nodes N1 and N2. FIGS. 2F and 2G are schematic diagrams of example slew rate control circuits according to an embodiment of the disclosure. In FIG. 2F, a slew rate control circuit 200F includes an NMOS transistor capacitive device 202F which is the same as the NMOS transistor capacitive device 202A, except that the body (B) is coupled to a terminal or a line to be supplied with VSS. Likewise, in FIG. 2G, a slew rate control circuit 200G includes a PMOS transistor capacitive device 202G which is the same as the PMOS transistor capacitive device 202B, except that the body (B) is supplied with VDD. This configuration including the transistor body supplied with the fixed voltage can be similarly applied to the other example capacitive devices described herein. The configuration is also applicable to the capacitive devices of the serially-coupled slew rate control circuits. Furthermore, in the case where the inverter 201 is an inverter including a transistor, such as a PMOS transistor inverter and a NMOS transistor inverter, a body of the transistor of the inverter 201 may also be coupled to the power supply terminal or any other terminals or lines as appropriate to be supplied with the fixed voltage, such as power supply potentials VDD and VSS.

In still some embodiments, the slew rate control circuit may include a logic circuit other than the inverter (NOT) 201, such as NAND, NOR, and the like. FIG. 2H is a schematic diagram of an example slew rate control circuit including a NAND logic circuit according to an embodiment of the disclosure. As one example, in FIG. 2H, a slew rate control circuit 200H includes a NAND 201H on the circuit input side and a capacitive device 202H on the circuit output side. One terminal of the capacitive device 202H is coupled to an output of the NAND 201H at the node N2. Another terminal of the capacitive device 202H is coupled to one of inputs of the NAND 201H at the node N1. The capacitive device 202H is the same as the PMOS transistor capacitive device 202D with the gate (G) coupled to the node NI and the source(S), the drain (D), and the body (B) coupled to each other at the node N3 and coupled to the node N2. The capacitive device 202H can be an NMOS transistor capacitive device. The capacitive device 202H can be serially coupled with any of the slew rate control circuits 200A-200G. In some instances, the capacitive device 202H may have the transistor body coupled to an appropriate terminal or line to be supplied with the fixed voltage in a similar manner to the capacitive device 202G (in the case of the PMOS transistor) or 202F (in the case of the NMOS transistor).

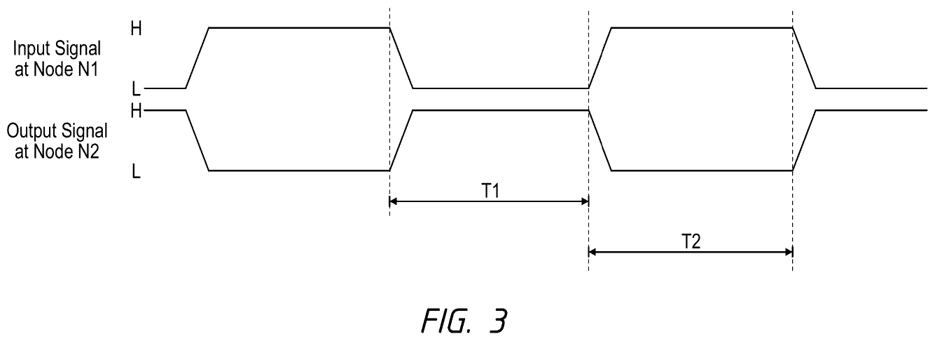

FIG. 3 is a timing diagram of an example transistor capacitive device according to an embodiment of the disclosure. The example transistor capacitive device may include at least one of the capacitive devices 202A-202D of the slew rate control circuits 200A-200D of FIGS. 2A-2D. During signal transition as illustrated, the transistor works as a capacitor. For example, during a first transition period T1 of input and output signals of the inverter 201 between a high level (H) and a low level (L), the gate (G) of the transistor capacitive device may turn and stay H while the source(S), the drain (D), and the body (B) of the transistor capacitive device may turn and stay L. This generates a negative region where there is effective capacitance by a negative channel. During a second transition period T2 of the input and output signals, the gate (G) may turn and stay L while the source(S), the drain (D), and the body (B) may turn and stay H. This generates a positive region where there is effective capacitance by a positive channel. Accordingly, the present embodiments realize the slew rate control circuits with greater total capacitance without an increase in capacitive device size.

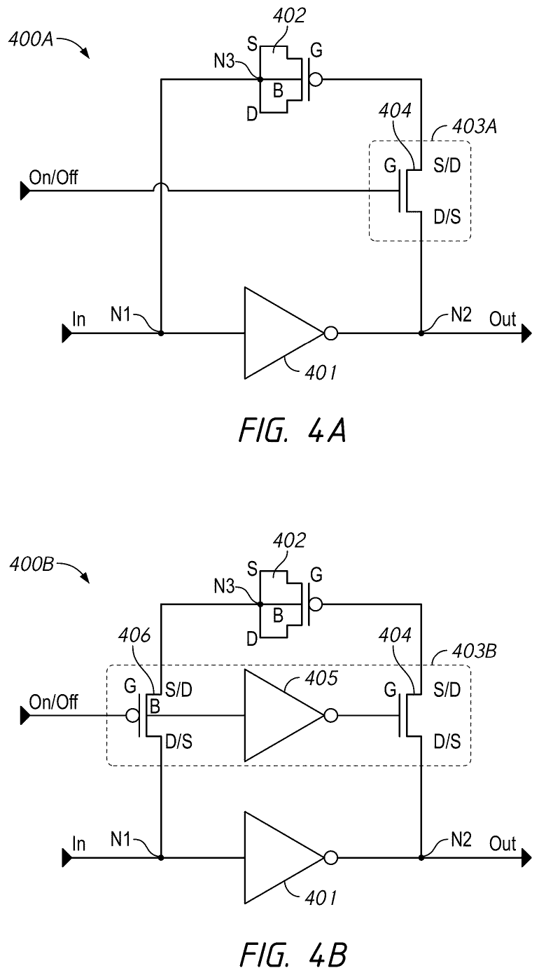

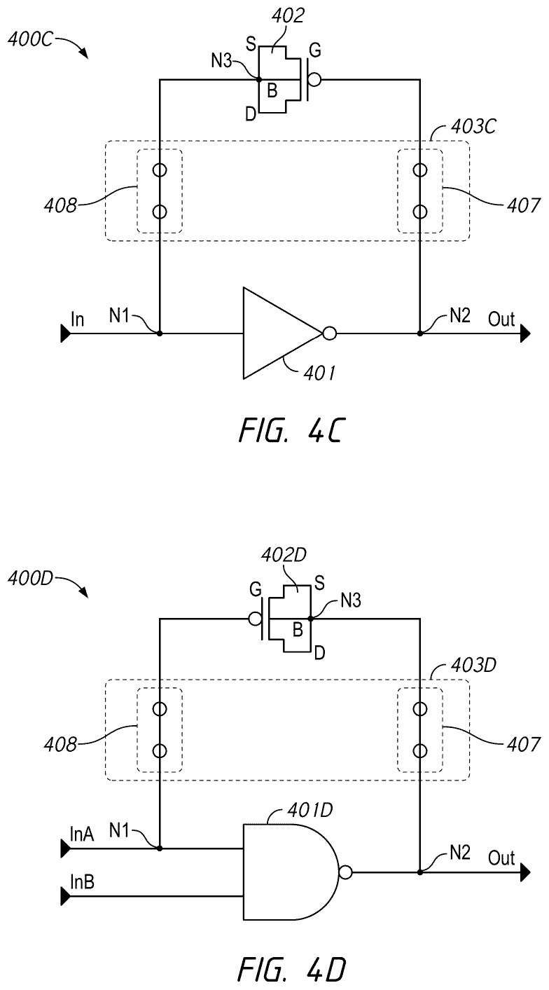

FIGS. 4A-4D are schematic diagrams of example slew rate control circuits and example switch circuits according to an embodiment of the disclosure. The slew rate control circuits described above may be turned on and off or connected and disconnected by switch circuits. As one example, as shown in FIG. 4A, a slew rate control circuit 400A includes an inverter 401 and an PMOS transistor capacitive device 402 which have the same configurations as the inverter 201 and the PMOS transistor capacitive device 202B, respectively, of the slew rate control circuit 200B in FIG. 2B, except that the slew rate control circuit 400A can be turned on and off or connected and disconnected by a switch circuit 403A. The switch circuit 403A includes a NMOS transistor 404 as a switch arranged between a gate (G) of the PMOS transistor capacitive device 402 and the node N2. A source(S)/drain (D) of the NMOS transistor 404 is coupled to the gate (G) of the PMOS transistor capacitive device 402, and a drain (D)/source(S) of the NMOS transistor 404 is coupled to the node N2. A gate (G) of the NMOS transistor 404 is coupled to, for example, a gate control line to receive a gate control signal. With this configuration, the gate of the PMOS transistor capacitive device 402 is coupled to the node N2 via the NMOS transistor 404 so that the PMOS transistor capacitive device 402 can be connected to and disconnected from the node N2 by the NMOS transistor 404 based on the gate control signal.

As another example, as shown in FIG. 4B, a slew rate control circuit 400B, which corresponds to the slew rate control circuit 400A or 200B, includes a switch circuit 403B. The switch circuit 403B includes an inverter 405 and a PMOS transistor 406 in addition to the NMOS transistor 404. The gate (G) of the NMOS transistor 404 is coupled to an output of the inverter 405. An input of the inverter 405 is coupled to a body (B) of the PMOS transistor 406. In some instances, the input of the inverter 405 may be coupled to the power supply terminal or any other terminals or lines as appropriate to be supplied with a fixed voltage, such as power supply potential VDD. A source(S)/drain (D) of the PMOS transistor 406 is coupled to S-D-B of the PMOS transistor capacitive device 402 at the node N3. A drain (D)/source(S) of the PMOS transistor 406 is coupled to the input of the inverter 401 at the node N1. S-D-B of the PMOS transistor capacitive device 402 or the node N3 is thus coupled to the node N1 via the PMOS transistor 406. A gate (G) of the PMOS transistor 406 is coupled to, for example, a gate control line to receive a gate control signal. With this configuration, connection and disconnection of the PMOS transistor capacitive device 402 is controlled by the switch circuit 403B based on the gate control signal.

As still another example, as shown in FIG. 4C, a slew rate control circuit 400C includes a switch circuit 403C that includes metal routing switches 407 and 408. The metal routing switch 407 is arranged between the gate (G) of the PMOS transistor capacitive device 402 and the node N2. The metal routing switch 408 is arranged between the source(S)-drain (D)-body (B) or node N3 of the PMOS transistor capacitive device 402 and the node N1. The metal routing switch 407 may include conductive contacts. The metal routing switches 407 and 408 may connect and disconnect the PMOS transistor capacitive device 402 and the nodes N1 and N2 physically. For example, to disconnect the PMOS transistor capacitive device 402 from at least one of the nodes N1 and N2, at least corresponding one of the metal routing switches 407 and 408 is turned off or cut off.

The example shown in FIG. 4D includes a slew rate control circuit 400D and a switch circuit 403D. The slew rate control circuit 400D includes a NAND 401D in place of the inverter (NOT) 401. The slew rate control circuit 400D includes a PMOS transistor capacitive device 402D which has the same configuration as the PMOS transistor capacitive device 202D in FIG. 2D including the source(S)-drain (D)-body (B) coupled to each other at the node N3 and coupled to the node N2, except that the gate (G) is coupled to one of the inputs (InA and InB) of the NAND 401D at the node N1. The switch circuit 403D includes the metal routing switch 407 arranged between the nodes N2 and N3 and the metal routing switch 408 arranged between the node N1 and the gate (G) of the PMOS transistor capacitive device 402D. In all of the above embodiments, the PMOS transistor capacitive device 402 may be replaced with an NMOS transistor capacitive device, such as the NMOS transistor capacitive device 202A in FIG. 2A, and the same or substantially the same switch configurations can be applied.

In some embodiments, for example, in the case where the PMOS transistor capacitive device 402 has the mutually tied source(S)-drain (D)-body (B) configuration at the node N3 and coupled to the node N1 or N2, when the PMOS transistor capacitive device 402 is disconnected by the switch circuit 403A, 403B, or 403C, all of S-D-B as well as the gate (G) may be coupled to the power supply terminal or any other terminals or lines as appropriate to be supplied with the fixed voltage, such as power supply potential VDD (or VSS in the case of the NMOS transistor capacitive device). If the PMOS transistor capacitive device 402 has only the source(S) and drain (D) tied together at the node N3 and coupled to the node N1 or N2 whereas the base (B) is being supplied with VDD in a similar manner to the configuration in FIG. 2G, then upon disconnection, S-D and G will be switched to VDD while B remains with VDD.

With the above switch configurations according to the present embodiments, it is possible to flexibly adjust the total capacitance size of the slew rate control circuit by turning on and off or connecting and disconnecting the capacitive device. The same or substantially the same advantages can be achieved for the PMOS transistor capacitive device and the NMOS transistor capacitive device.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a logic circuit configured to receive a target signal; and
a capacitive device including one terminal coupled to a first node on an output side of the logic circuit and another terminal coupled to a second node on an input side of the logic circuit.

2. The apparatus according to claim 1, wherein
the capacitive device comprises a transistor,
a gate of the transistor is coupled to one of the first node and the second node, and
at least a body of the transistor is coupled to another of the first node and the second node.

3. The apparatus according to claim 2, wherein a source and a drain of the transistor are coupled to the other of the first node and the second node.

4. The apparatus according to claim 2, wherein the body of the transistor is supplied with a fixed voltage.

5. The apparatus according to claim 4, wherein
the transistor of the capacitive device is a first transistor,
the logic circuit comprises an inverter including a second transistor, and
a body of the second transistor of the inverter is supplied with the fixed voltage.

6. The apparatus according to claim 2 wherein
the transistor of the capacitive device is a first transistor,
the logic circuit comprises an inverter including a second transistor, and
the body of the first transistor of the capacitive device is electrically independent of a body of the second transistor of the inverter.

7. The apparatus according to claim 1, wherein
the capacitive device comprises a transistor,
a gate of the transistor is coupled to one of the first node and the second node, and
a source and a drain of the transistor is coupled to another of the first node and the second node.

8. The apparatus according to claim 7, wherein a body of the transistor is coupled to the other of the first node and the second node.

9. The apparatus according to claim 7, wherein a body of the transistor is supplied with a fixed voltage.

10. The apparatus according to claim 9, wherein
the transistor of the capacitive device is a first transistor,
the logic circuit comprises an inverter including a second transistor, and
a body of the second transistor of the inverter is supplied with the fixed voltage.

11. The apparatus according to claim 7 wherein
the transistor of the capacitive device is a first transistor,
the logic circuit comprises an inverter including a second transistor, and
a body of the first transistor of the capacitive device is electrically independent of a body of the second transistor of the inverter.

12. The apparatus according to claim 1, wherein
the capacitive device is a first capacitive device including a first transistor,
the apparatus further comprises a second capacitive device including a second transistor,
gates of the first and second transistors are coupled to one of the first node and the second node, and
sources, drains, and bodies of the first and second transistors are coupled to another of the first node and the second node.

13. The apparatus according to claim 12, wherein the source, the drain, and the body of each of the first and second transistors are coupled to each other at a third node, and the third node is coupled to the other of the first node and the second node.

14. The apparatus according to claim 1, further comprises a switch circuit configured to connect and disconnect the capacitive device to and from at least one of the first node and the second node.

15. The apparatus according to claim 14, wherein the switch circuit includes a transistor coupled between the capacitive device and the first node.

16. The apparatus according to claim 14, wherein the switch circuit includes a first transistor coupled between the capacitive device and the first node, a second transistor coupled between the capacitive device and the second node, and an inverter coupled between the first transistor and the second transistor.

17. The apparatus according to claim 14, wherein the switch circuit includes a first metal contact switch coupled between the capacitive device and the first node, and further includes a second metal contact switch coupled between the capacitive device and the second node.

18. An apparatus, comprising:
an inverter configured to receive a target signal for slew rate control; and
a capacitive device comprising a MOS transistor, the MOS transistor including a gate coupled to a first node on one of an input side and an output side of the inverter, and further including a source, a drain, and a body coupled to a second node on another of the input side and the output side of the inverter, wherein
the source, the drain, and the body of the MOS transistor are coupled to each other at a third node, and the third node is coupled to the second node.

19. The apparatus according to claim 18, wherein the MOS transistor is an n-channel type MOS transistor or a p-channel type MOS transistor.

20. The apparatus according to claim 18, wherein
the MOS transistor is a first MOS transistor, and the gate, the source, the drain, and the body thereof are a first gate, a first source, a first drain, and a second body,
the capacitive device further comprises a second MOS transistor, the second MOS transistor including a second gate coupled to the first node, and further including a second source, a second drain, and a second body coupled to the second node.

21. An apparatus, comprising:
a memory device; and
a slew rate control circuit configured to control a slew rate of a signal for the memory device, the slew rate control circuit including:
a logic circuit configured to receive the signal; and
a capacitive device including one terminal coupled to a first node on an output side of the logic circuit to provide first capacitance at the first node, and further including another terminal coupled to a second node on an input side of the logic circuit to provide second capacitance at the second node.

22. The apparatus according to claim 21, wherein
the capacitive device comprises a MOS transistor,
the first node is coupled to one of a gate of the MOS transistor and a source-drain-body node of the MOS transistor, and
the second node is coupled to another of the gate of the MOS transistor and the source-drain-body node of the MOS transistor.
